(19) United States
(12) Patent Application Publication
(10) Pub. No.: US 2025/0246221 A1
(43) Pub. Date: Jul. 31, 2025

(54) SEMICONDUCTOR DEVICE PERFORMING REFRESH OPERATION

(71) Applicant: MICRON TECHNOLOGY, INC., BOISE, ID (US)

(72) Inventors: Atsushi Hatakeyama, Tokyo (JP); Yoshifumi Mochida, Sagamihara (JP)

(73) Assignee: MICRON TECHNOLOGY, INC., Boise, ID (US)

(21) Appl. No.: 19/008,233

(22) Filed: Jan. 2, 2025

Related U.S. Application Data
(60) Provisional application No. 63/627,616, filed on Jan. 31, 2024.

(51) Int. Cl. G11C 11/406; G11C 11/4074; G11C 11/4076

(52) U.S. Cl. CPC G11C 11/406; G11C 11/4074; G11C 11/4076

(57) ABSTRACT

An example system includes: a memory chip having a plurality of external terminals; and a controller chip coupled to the plurality of external terminals of the memory chip and configured to issue, via some of the plurality of external terminals, a plurality of commands including a power down entry command and a refresh command. The memory chip is configured to: change an operation mode from a normal mode to a power down mode when the power down entry command is issued from the controller chip; perform a refresh operation when the refresh command is issued from the controller chip in the normal mode; and perform the refresh operation when the controller chip brings one of the plurality of external terminals into a first predetermined level in the power down mode.

### CROSS-REFERENCE TO RELATED APPLICATIONS

This application claims the filing benefit of U.S. Provisional Application No. 63/627,616, filed Jan. 31, 2024. This application is incorporated by reference herein in its entirety and for all purposes.

### BACKGROUND

A typical DRAM has a power down mode that reduces current consumption during standby. When the DRAM is in the power down mode, a command other than a power down exit command is not accepted.

In a case where a self-refresh operation is not performed in the power down mode, data stored in the DRAM can be retained by causing the DRAM to exit from the power down mode by the power down exit command once and then submitting a refresh command to cause the DRAM to enter again the power down mode. However, in this method, an internal circuit such as a command decoder is activated in a period from submission of the power down exit command to re-submission of a power down entry command, and therefore current consumption occurs.

### BRIEF DESCRIPTION OF THE DRAWINGS

FIG. 1 is a block diagram showing a system according to an embodiment of the present disclosure;

FIG. 2 is a block diagram showing a configuration of a DRAM chip;

FIG. 3 is a circuit diagram showing a configuration of a main part of an access control circuit;

FIG. 4 is a timing chart for explaining an operation of the DRAM chip; and

FIG. 5 is a circuit diagram showing a configuration of a main part of an access control circuit according to a modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

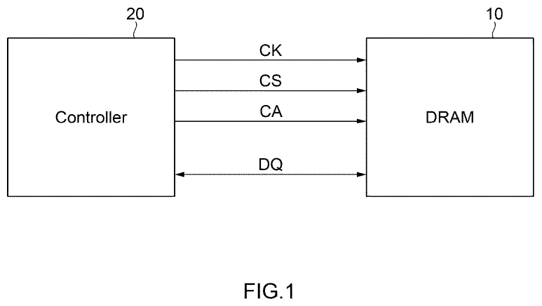

FIG. 1 is a block diagram showing a system according to an embodiment of the present disclosure. The system shown in FIG. 1 includes a DRAM chip 10 and a controller chip 20 controlling the DRAM chip 10. The controller chip 20 supplies an external clock signal CK, a chip selection signal CS, a command address signal CA, and the like to the DRAM chip 10. Read data DQ read out from the DRAM chip 10 is supplied to the controller chip 20. Write data DQ output from the controller chip 20 is input to the DRAM chip 10.

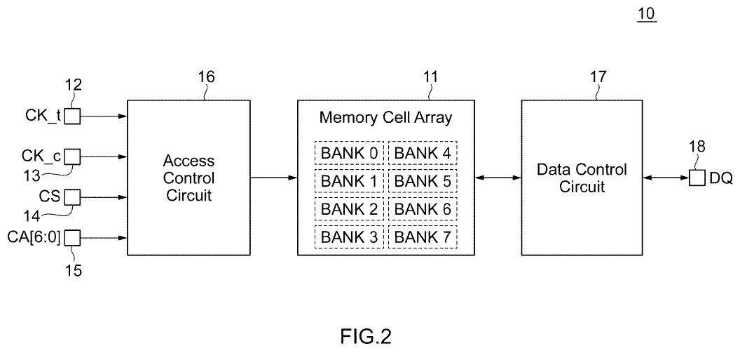

FIG. 2 is a block diagram showing a configuration of the DRAM chip 10. The DRAM chip 10 shown in FIG. 2 is, for example, an LPDDR5 DRAM and includes a memory cell array 11. The memory cell array 11 has eight memory banks including memory banks BANK0 to BANK7, for example. When access is made to the memory cell array 11, the chip selection signal CS is input to a chip selection terminal 14, and the command address signal CA is input to a command address terminal 15, both inputs being performed in synchronization with external clock signals CK_t and CK_c respectively input to clock terminals 12 and 13. The command address signal CA has a 7-bit configuration including CA[0] to CA[6], for example. The external clock signals CK_t and CK_c, the chip selection signal CS, and the command address signal CA[6:0] are supplied to an access control circuit 16. The access control circuit 16, for example, decodes the command address signal CA[6:0] and counts the latency.

When a command included in the command address signal CA[6:0] indicates a read command, the access control circuit 16 makes read-access to a memory cell included in the memory cell array 11 based on an address included in the command address signal CA[6:0]. The read data DQ read out from the memory cell accessed here is output to outside from a data I/O terminal 18 via a data control circuit 17. When the command included in the command address signal CA[6:0] indicates a write command, the write data DQ input from the outside to the data I/O terminal 18 is transferred to the memory cell array 11 via the data control circuit 17. The write data DQ having been transferred to the memory cell array 11 is written to the memory cell included in the memory cell array 11 based on the address included in the command address signal CA[6:0]. Further, when the command included in the command address signal CA[6:0] indicates a refresh command, the access control circuit 16 performs a refresh operation for a predetermined memory cell in the memory cell array 11.

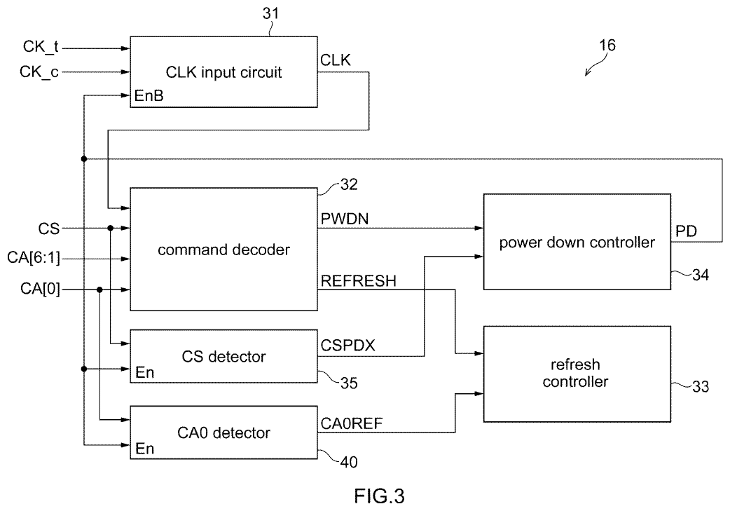

FIG. 3 is a circuit diagram showing a configuration of the main part of the access control circuit 16. As shown in FIG. 3, the access control circuit 16 includes a clock input circuit 31 and a command decoder 32. The clock input circuit 31 generates an internal clock signal CLK based on the external clock signals CK_t and CK_c that are complementary to each other. The internal clock signal CLK is supplied to various internal circuits including the command decoder 32. The command decoder 32 generates various internal signals based on the chip selection signal CS and the command address signal CA[6:0]. For example, the command decoder 32 activates a refresh signal REFRESH when the command address signal CA[6:0] indicates a refresh command, and activates a power down signal PWDN when the command address signal CA[6:0] indicates a power down entry command. The refresh signal REFRESH is supplied to a refresh control circuit 33. The refresh control circuit 33 performs a refresh operation for the memory cell array 11 when the refresh signal REFRESH is activated. The power down signal PWDN is supplied to a power down control circuit 34. The power down control circuit 34 activates a power down signal PD to a high level when the power down signal PWDN is activated. When the power down signal PD is changed from a low level to a high level, the DRAM chip 10 enters a power down mode. The power down signal PD is supplied to the clock input circuit 31. The clock input circuit 31 is activated when the power down signal PD is at a low level, and is deactivated when the power down signal PD is at a high level. That is, the clock input circuit 31 is activated in a normal mode and is deactivated in the power down mode. Accordingly, generation of the internal clock signal CLK is stopped in the power down mode, and therefore power consumption in various circuits operating in synchronization with the internal clock signal CLK such as the command decoder 32 is reduced.

The chip selection signal CS is also supplied to a CS detector 35. The CS detector 35 is activated when the power down signal PD is at a high level, i.e., in the power down mode, and activates a power down signal CSPDX when the level of the chip selection signal CS exceeds a predetermined level. The level of the chip selection signal CS required for activation of the power down signal CSPDX may be out of a range of the amplitude of the chip selection signal CS in the normal mode. For example, the level of the chip selection signal CS required for activation of the power down signal CSPDX may be higher than the high level of the chip selection signal CS supplied in the normal mode or may be lower than the low level of the chip selection signal CS supplied in the normal mode. The power down signal CSPDX is supplied to the power down control circuit 34. The power down control circuit 34 activates the power down signal PD to a low level when the power down signal CSPDX is activated. When the power down signal PD is changed from a high level to a low level, the DRAM chip 10 exits from the power down mode and returns to the normal mode. That is, the chip selection signal CS exceeding the predetermined level in the power down mode indicates a power down exit command. When the power down exit command is issued, the DRAM chip 10 returns from the power down mode to the normal mode.

The command address signal CA[0] is also supplied to a CAO detector 40. The CAO detector 40 is activated when the power down signal PD is at a high level, i.e., in the power down mode, and activates a refresh signal CA0REF when the level of the command address signal CA[0] exceeds a predetermined level. The level of the command address signal CA[0] required for activation of the refresh signal CA0REF may be out of a range of the amplitude of the command address signal CA[0] in the normal mode. For example, the level of the command address signal CA[0] required for activation of the refresh signal CA0REF may be higher than the high level of the command address signal CA[0] supplied in the normal mode or may be lower than the low level of the command address signal CA[0] supplied in the normal mode. The refresh signal CA0REF is supplied to the refresh control circuit 33. The refresh control circuit 33 performs a refresh operation for the memory cell array 11 when the refresh signal CA0REF is activated. That is, the command address signal CA[0] exceeding the predetermined level in the power down mode indicates a refresh command. As described above, the DRAM chip 10 according to the present embodiment can accept a special refresh command from the external controller chip 20 while remaining in the power down mode.

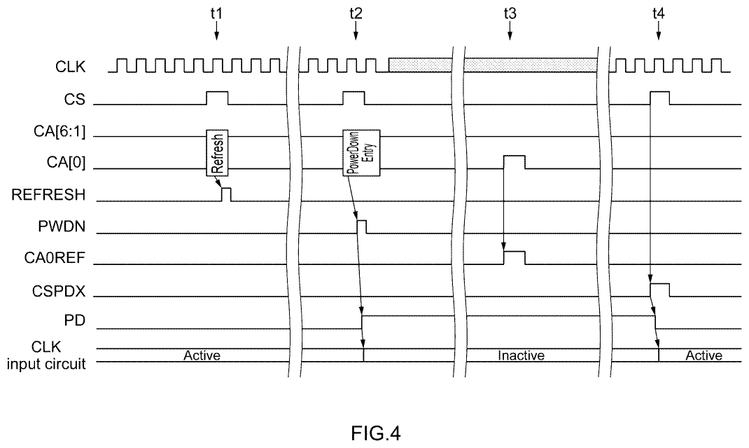

FIG. 4 is a timing chart for explaining an operation of the DRAM chip 10 according to the present embodiment. In the example shown in FIG. 4, a power down entry command is issued at a time t2, and a power down exit command is issued at a time t4. Therefore, in a period before the time t2 and a period after the time t4, the power down signal PD is at a low level, and the DRAM chip 10 operates in a normal mode. Meanwhile, in a period from the time t2 to the time t4, the power down signal PD is at a high level, and the DRAM chip 10 is in the power down mode. In the example shown in FIG. 4, a refresh command is issued at a time t1. Since the DRAM chip 10 is in the normal mode at the time t1, the refresh command is expressed by the command address signal CA[6:0]. Another refresh command is issued at a time t3 that is in the power down mode. Since the DRAM chip 10 is in the power down mode at the time t3, the refresh command is expressed by the command address signal CA[0].

As described above, in the present embodiment, a refresh operation can be performed by changing the command address signal CA[0] to a predetermined level while the DRAM chip 10 is in the power down mode. That is, the refresh operation can be performed only by changing the command address signal CA[0] to the predetermined level in the power down mode, without executing a series of control that causes the DRAM chip 10 to exit from the power down mode by a power down exit command once and then submits a refresh command to bring the DRAM chip 10 into the power down mode again. Accordingly, current consumption generated in the above series of control can be reduced.

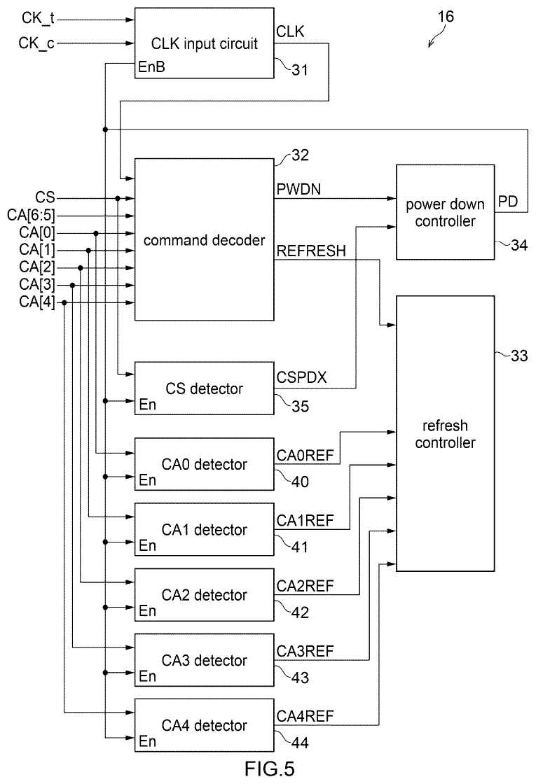

FIG. 5 is a circuit diagram showing a configuration of the main part of the access control circuit 16 according to a modification. In the example shown in FIG. 5, a CA1 detector 41, a CA2 detector 42, a CA3 detector 43, and a CA4 detector 44 respectively receiving command address signals CA[1], CA[2], CA[3], and CA[4] are additionally provided. The CA1 detector 41 to the CA4 detector 44 are all activated when the power down signal PD is at a high level, and activate corresponding refresh signals CA1REF to CA4REF when the corresponding command address signals CA[1] to CA[4] exceed a predetermined level, respectively. The refresh signal CA1REF is used for, for example, distinguishing an all-bank refresh operation and a per-bank refresh operation. In a case where a refresh command using the command address signal CA[0] is issued in a power down mode, for example, when the refresh signal CA1REF indicates the all-bank refresh operation, a refresh operation is performed for the eight memory banks BANK0 to BANK7 shown in FIG. 2. The refresh signals CA2REF to CA4REF indicate an address of a memory bank to be refreshed, for example, when the refresh signal CA1REF indicates the per-bank refresh operation. In a case where the refresh command using the command address signal CA[0] is issued in the power down mode, for example, when the refresh signal CA1REF indicates the per-bank refresh operation, the refresh operation is performed for one of the eight memory banks BANK to BANK7 shown in FIG. 2 which is indicated by the refresh signals CA2REF to CA4REF.

Although the command address signal CA[0] is used as a special refresh command in a power down mode in the embodiment described above, it goes without saying that the present invention is not limited thereto. Therefore, another bit configuring the command address signal CA[6:0], for example, the command address signal CA[6] may be used as the special refresh command in the power down mode. Further, the external clock signal CK or the write data DQ may be used as the special refresh command in the power down mode.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a plurality of external terminals including a plurality of command terminals;
a memory cell array;
a refresh controller configured to control a refresh operation of the memory cell array;
a command decoder coupled to the plurality of command terminals and configured to:
activate a first refresh signal responsive to a first refresh command supplied to the plurality of command terminals; and
activate a first power down signal responsive to a power down entry command supplied to the plurality of command terminals; and
a power down controller configured to change an operation mode from a normal mode to a power down mode responsive to the first power down signal,
wherein the refresh controller is configured to:
perform the refresh operation responsive the first refresh signal in the normal mode; and
perform the refresh operation responsive a second refresh command supplied to one of the plurality of external terminals in the power down mode.

2. The apparatus of claim 1,
wherein the plurality of external terminals include a clock terminal supplied with an external clock signal,
wherein the apparatus further comprises a clock input circuit coupled to the clock terminal and configured to generate an internal clock signal based on the external clock signal, and
wherein the clock input circuit is activated in the normal mode and deactivated in the power down mode.

3. The apparatus of claim 1,
wherein one of the plurality of command terminals is supplied with a power down exit command,
wherein the apparatus further comprises a first detector coupled to the one of the plurality of command terminals and configured to activate a second power down signal based on the power down exit command, and
wherein the power down controller is configured to change an operation mode from the power down mode to the normal mode responsive to the second power down signal.

4. The apparatus of claim 3, wherein the first detector is activated in the power down mode and deactivated in the normal mode.

5. The apparatus of claim 1, further comprising a second detector coupled to the one of the plurality of external terminals and configured to activate a second refresh signal based on the second refresh command,
wherein the refresh controller is configured to perform the refresh operation responsive the second refresh signal, and
wherein the second detector is activated in the power down mode and deactivated in the normal mode.

6. The apparatus of claim 5, wherein the one of the plurality of external terminals is included in the plurality of command terminals.

7. An apparatus comprising:
a memory cell array;
a plurality of command terminals supplied with an external command;
a command decoder coupled to the plurality of command terminals and configured to activate a first power down signal when the external command indicates a power down entry command;
a power down controller configured to change an operation mode from a normal mode to a power down mode responsive to the first power down signal; and
a refresh controller configured to perform a refresh operation of the memory cell array when a potential of a first one of the plurality of command terminals exceeds a first predetermined level in the power down mode.

8. The apparatus of claim 7,
wherein the command decoder is configured to activate a first refresh signal when the external command indicates a refresh command, and
wherein the refresh controller is configured to perform the refresh operation responsive to the first refresh signal in the normal mode.

9. The apparatus of claim 8, further comprising a first detector coupled to the first one of the plurality of command terminals and configured to activate a second refresh signal when the potential of the first one of the plurality of command terminals exceeds the first predetermined level in the power down mode,
wherein the refresh controller is configured to perform the refresh operation responsive to the second refresh signal in the power down mode.

10. The apparatus of claim 9, wherein the first detector is activated in the power down mode and deactivated in the normal mode.

11. The apparatus of claim 7, wherein the power down controller is configured to change an operation mode from the power down mode to the normal mode when a potential of a second one of the plurality of command terminals exceeds a second predetermined level in the power down mode.

12. The apparatus of claim 11, further comprising a second detector coupled to the second one of the plurality of command terminals and configured to activate a second power down signal when the potential of the second one of the plurality of command terminals exceeds the second predetermined level in the power down mode,
wherein the power down controller is configured to change an operation mode from the power down mode to the normal mode responsive the second power down signal.

13. The apparatus of claim 12, wherein the second detector is activated in the power down mode and deactivated in the normal mode.

14. The apparatus of claim 7, further comprising:
a clock terminal supplied with an external clock signal; and
a clock input circuit coupled to the clock terminal and configured to generate an internal clock signal based on the external clock signal,
wherein the clock input circuit is activated in the normal mode and deactivated in the power down mode.

15. The apparatus of claim 14, wherein the internal clock signal is supplied to the command decoder.

16. A system comprising:
a memory chip having a plurality of external terminals; and
a controller chip coupled to the plurality of external terminals of the memory chip and configured to issue, via some of the plurality of external terminals, a plurality of commands including a power down entry command and a refresh command,
wherein the memory chip is configured to:
change an operation mode from a normal mode to a power down mode when the power down entry command is issued from the controller chip;
perform a refresh operation when the refresh command is issued from the controller chip in the normal mode; and
perform the refresh operation when the controller chip brings one of the plurality of external terminals into a first predetermined level in the power down mode.

17. The system of claim 16,
wherein the memory chip includes a first detector coupled to the one of the plurality of external terminals, and
wherein the first detector is activated in the power down mode and configured to detect that a potential of the one of the plurality of external terminals reaches the first predetermined level.

18. The system of claim 17,
wherein the plurality of external terminals include a plurality of command terminals supplied with the plurality of commands, and
wherein the one of the plurality of external terminals is included in the plurality of command terminals.

19. The system of claim 18, wherein the memory chip is configured to change an operation mode from the power down mode to the normal mode when the controller chip brings another of the plurality of external terminals into a second predetermined level in the power down mode.

20. The system of claim 19,
wherein the memory chip includes a second detector coupled to the another of the plurality of external terminals, and
wherein the second detector is activated in the power down mode and configured to detect that a potential of the another of the plurality of external terminals reaches the second predetermined level.
